(19) United States
(12) Patent Application Publication
(10) Pub. No.: US 2025/0185157 A1
(43) Pub. Date: Jun. 5, 2025

(54) WIRING BOARD

(71) Applicant: KYOCERA Corporation, Kyoto-shi, Kyoto (JP)

(72) Inventors: Suguru KADOWAKI, Moriyama-shi (JP); Tomoko NAKAMURA, Satsumasendai-shi (JP)

(73) Assignee: KYOCERA Corporation, Kyoto-shi, Kyoto (JP)

(21) Appl. No.: 18/842,309

(22) PCT Filed: Feb. 22, 2023
(86) PCT No.: PCT/JP2023/006465

§ 371 Date: Aug. 28, 2024

(30) Foreign Application Priority Data
Feb. 28, 2022 (JP) 2022-029033

(51) Int. Cl. H05K 1/02; H05K 1/11; H05K 1/18

(52) U.S. Cl. CPC H05K 1/0271; H05K 1/115; H05K 1/181; H05K 2201/09636; H05K 2201/10121; H05K 2201/10212

(57) ABSTRACT

A wiring board according to the present disclosure includes a first insulation layer, a first laminate portion, a second laminate portion, a second insulation layer, a third insulation layer, a first mounting region, a second mounting region, a first electrical conductor layer having a planar shape, a second electrical conductor layer, and a solder resist having an opening from which a part of the first electrical conductor layer is exposed. In a plane perspective view, in a frame-shaped region between an outer peripheral edge of the first mounting region and an outer peripheral edge of the second mounting region, a through-hole conductor that connects the first electrical conductor layer and the second electrical conductor layer is located across the edge of the opening.

### TECHNICAL FIELD

The present invention relates to a wiring board and a mounting structure using the same.

### BACKGROUND OF INVENTION

A flip chip ball grid array (FC-BGA) or the like is known as an LSI package in which an LSI chip is mounted on a wiring board. For example, as disclosed in Patent Document 1, a stiffener is provided on a wiring board that is used for such an LSI package for the purpose of reinforcement.

### CITATION LIST

### Patent Literature

Patent Document 1: JP 3173459 B

### SUMMARY

### Solution to Problem

A wiring board according to the present disclosure includes a first insulation layer having a first surface and a second surface located on an opposite side to the first surface, a first laminate portion located on the first surface and including insulation layers, a second laminate portion located on the second surface and including insulation layers, a second insulation layer located as an outermost layer of the insulation layers in the first laminate portion, a third insulation layer located as an outermost layer in the insulation layers of the second laminate portion, a first mounting region located on a first outer surface on the opposite side to the first surface in the second insulation layer, a second mounting region located on the first outer surface to surround the first mounting region in the second insulation layer, a first electrical conductor layer having a planar shape and located on a second outer surface on an opposite side to the second surface in the third insulation layer, a second electrical conductor layer located on a second inner surface on the second surface side in the third insulation layer, and a solder resist covering the second outer surface of the third insulation layer and the first electrical conductor layer, and having an opening from which a part of the first electrical conductor layer is exposed. In a plane perspective view, in a frame-shaped region between an outer peripheral edge of the first mounting region and an outer peripheral edge of the second mounting region, a through-hole conductor configured to connect the first electrical conductor layer and the second electrical conductor layer is located across an edge of the opening.

A mounting structure according to the present disclosure includes the wiring board described above, an electronic component located in the first mounting region, a stiffener located in the second mounting region, and an external substrate including an electrode. The first electrical conductor layer inside the opening and the electrode are connected to each other via a solder.

### BRIEF DESCRIPTION OF THE DRAWINGS

FIG. 1 is an explanatory diagram for explaining a state in which an electronic component and a stiffener are mounted on a wiring board according to one embodiment of the present disclosure.

FIG. 2 is an explanatory diagram for explaining a state of the wiring board according to the one embodiment of the present disclosure when viewed from a direction indicated by an arrow A in FIG. 1.

FIG. 3 is an explanatory diagram for explaining a state of the wiring board according to the one embodiment of the present disclosure when viewed from a direction indicated by an arrow B in FIG. 1.

FIG. 4 is an explanatory diagram for explaining an example of a through-hole conductor included in the wiring board according to the one embodiment of the present disclosure.

FIG. 5 is an explanatory diagram for explaining variations of the through-hole conductor.

FIG. 6 is an explanatory diagram for explaining variations of the shape of an opening formed in a solder resist when the wiring board according to the one embodiment of the present disclosure is viewed from the direction indicated by the arrow B in FIG. 1.

FIG. 7 is a graph showing simulation results related to a known mounting structure and a mounting structure according to the present disclosure.

FIG. 8 shows a cross-sectional view of a simulation model for the known mounting structure and simulation results thereof.

FIG. 9 shows a cross-sectional view of a simulation model in which two circular through-hole conductors are provided for one opening in a plane perspective view in the one embodiment of the present disclosure, and simulation results thereof.

FIG. 10 shows a cross-sectional view of a simulation model in which six circular through-hole conductors are provided for one opening in a plane perspective view in the one embodiment of the present disclosure, and simulation results thereof.

FIG. 11 shows a cross-sectional view of a simulation model in which two arc-shaped through-hole conductors are provided for one opening in a plane perspective view in the one embodiment of the present disclosure, and simulation results thereof.

FIG. 12 shows a cross-sectional view of a simulation model in which arc-shaped through-hole conductors are provided so as to be closer to the outer side of the opening in the one embodiment of the present disclosure, and simulation results thereof.

FIG. 13 shows a cross-sectional view of a simulation model in which arc-shaped through-hole conductors are provided so as to be closer to the inner side of the opening in the one embodiment of the present disclosure, and simulation results thereof.

FIG. 14 shows a cross-sectional view of a simulation model in which an annular through-hole conductor is provided in the one embodiment of the present disclosure, and simulation results thereof.

FIG. 15 shows a cross-sectional view of a simulation model in which an elliptical opening is formed in the solder resist in the one embodiment of the present disclosure when viewed from the direction indicated by the arrow B in FIG. 1, and simulation results thereof.

FIG. 16 shows a cross-sectional view of a simulation model in which six circular through-hole conductors are provided for one elliptical opening formed in the solder resist in the one embodiment of the present disclosure when viewed from the direction indicated by the arrow B in FIG. 1, and simulation results thereof.

FIG. 17 shows a cross-sectional view of a simulation model in which two arc-shaped through-hole conductors are provided for one elliptical opening formed in the solder resist in the one embodiment of the present disclosure when viewed from the direction indicated by the arrow B in FIG. 1, and simulation results thereof.

FIG. 18 shows a cross-sectional view of a simulation model in which an elliptical through-hole conductor is provided for one elliptical opening formed in the solder resist in the one embodiment of the present disclosure when viewed from the direction indicated by the arrow B in FIG. 1, and simulation results thereof.

FIG. 19 is a diagram showing a stress value generated in the opening according to each of the simulation results shown in FIGS. 15 to 18.

### DESCRIPTION OF EMBODIMENTS

In a known wiring board, the wiring board is likely to warp due to a difference in the coefficient of thermal expansion between a substrate, a chip, and a stiffener. In particular, due to the warping, stress is likely to be concentrated in a region between the chip and the stiffener, and cracks are likely to occur in a plane conductor (in particular, a plane conductor around a solder) present on a surface (opposite surface) facing this region. Thus, a wiring board is demanded in which stress is less likely to be concentrated in the region between the chip and the stiffener and in which cracks are less likely to occur even when the wiring board is used in an environment in which the temperature repeatedly becomes high and low.

In a wiring board according to the present disclosure, as described in a section for Solution to Problem, in a plane perspective view, in a frame-shaped region between the outer peripheral edge of a first mounting region and the outer peripheral edge of a second mounting region, a through-hole conductor that connects a first electrical conductor layer and a second electrical conductor layer is located across the edge of an opening. Thus, in the wiring board according to the present disclosure, even when the wiring board is used in the environment in which the temperature repeatedly becomes high and low, stress is less likely to be concentrated in the region between the chip and the stiffener, and cracks are less likely to occur.

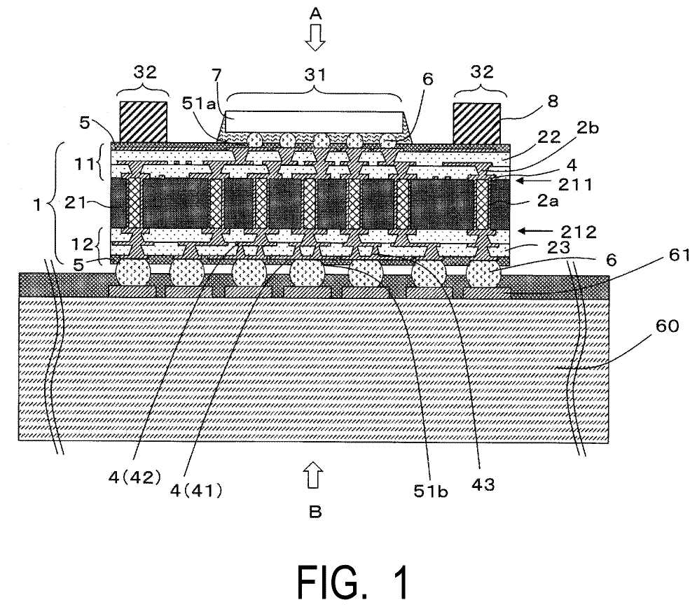

The wiring board according to one embodiment of the present disclosure will be described with reference to FIGS. 1 to 4. FIG. 1 is an explanatory diagram for explaining a state in which an electronic component and a stiffener are mounted on the wiring board according to the one embodiment of the present disclosure. As illustrated in FIG. 1, a wiring board 1 according to the one embodiment includes a first insulation layer 21, a first laminate portion 11, a second laminate portion 12, and a solder resist 5.

The first insulation layer 21 has a first surface 211 and a second surface 212 located on the opposite side to the first surface 211. The first surface 211 and the second surface 212 correspond to main surfaces of the first insulation layer 21. In the wiring board 1 according to the one embodiment, the first insulation layer 21 corresponds to a core insulation layer.

The first insulation layer 21 is not particularly limited as long as the first insulation layer 21 is formed of a material having an insulation property. Examples of the material having an insulation property include resins such as an epoxy resin, a bismaleimide-triazine resin, a polyimide resin, and a polyphenylene ether resin. Two or more types of these resins may be mixed and used. The thickness of the first insulation layer 21 is not particularly limited and is, for example, from 40 μm to 1800 μm.

The first insulation layer 21 may include a reinforcing material. Examples of the reinforcing material include insulation fabric materials such as glass fiber, glass non-woven fabric, aramid non-woven fabric, aramid fiber, and polyester fiber. Two or more types of reinforcing materials may be used in combination. An inorganic insulation filler made of, for example, silica, barium sulfate, talc, clay, glass, calcium carbonate, or titanium oxide may be dispersed in the first insulation layer 21.

A through-hole metal 2a is located in the first insulation layer 21 in order to electrically connect the upper and lower surfaces of the first insulation layer 21. The through-hole metal 2a is located inside a through hole penetrating from the first surface 211 to the second surface 212 of the first insulation layer 21. The through-hole metal 2a is formed of, for example, metal plating such as copper plating. The through-hole metal 2a is connected to electrical conductor layers 4 formed on both sides of the first insulation layer 21. The through-hole metal 2a may be formed only on an inner wall surface of the through hole, or the through hole may be filled with the through-hole metal 2a.

The first laminate portion 11 is located on the first surface 211 of the first insulation layer 21. The first laminate portion 11 has a structure in which the electrical conductor layer 4 and an insulation layer are alternately laminated. At least two of the electrical conductor layers 4 and one of the insulation layers are laminated in the first laminate portion 11. The electrical conductor layer 4 is not limited as long as the electrical conductor layer 4 is formed of a conductor such as metal. Specifically, the electrical conductor layer 4 is formed of a metal foil such as a copper foil, metal plating such as copper plating, or the like. The thickness of the electrical conductor layer 4 is not particularly limited, and is, for example, from 10 μm to 30 μm.

As the same as or similar to the first insulation layer 21, the insulation layer is not particularly limited as long as the insulation layer is formed of a material having an insulation property. Examples of the material having an insulation property include resins such as an epoxy resin, a bismaleimide-triazine resin, a polyimide resin, and a polyphenylene ether resin. Two or more types of these resins may be mixed and used. The insulation layers may be formed of the same resin or may be formed of different resins. The insulation layer and the first insulation layer 21 may be formed of the same resin, or may be formed of different resins.

An inorganic insulation filler made of, for example, silica, barium sulfate, talc, clay, glass, calcium carbonate, or titanium oxide may be dispersed in the insulation layer. The thickness of the insulation layer is not particularly limited and is, for example, from 5 μm to 50 μm. The insulation layers may have the same thickness, or may have different thicknesses.

A via-hole metal 2b for electrically connecting the layers is formed in the insulation layer. The via-hole metal 2b is located in a via-hole penetrating the upper and lower surfaces of the insulation layer. The via-hole metal 2b is formed of, for example, metal plating such as copper plating. The via-hole metal 2b is connected to the electrical conductor layers 4 located on both surfaces of the insulation layer. The via hole may be filled with the via-hole metal 2b, or the via-hole metal 2b may be located only on an inner wall surface of the via hole.

Of the insulation layers in the first laminate portion 11, the insulation layer located as the outermost layer is defined as a second insulation layer 22. That is, the insulation layer farthest from the first surface 211 is the second insulation layer 22. In the wiring board 1 illustrated in FIG. 1, since the first laminate portion 11 includes two of the insulation layers, the upper insulation layer is the second insulation layer 22.

As illustrated in FIG. 1, the solder resist 5 may be located on a surface (a first outer surface) of the first laminate portion 11. The solder resist 5 is formed of a resin, and examples of the resin include an acrylic-modified epoxy resin. An opening 51a is provided in the solder resist 5 in order to electrically connect the electrical conductor layer 4 and an electrode of an electronic component 7 via a solder 6. The opening 5 la is provided in a first mounting region 31, for example.

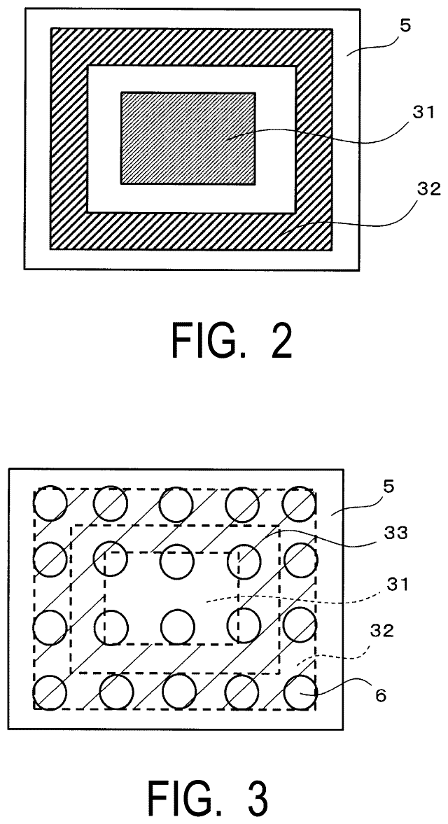

The first mounting region 31 is a region for mounting the electronic component 7, and is located on the outermost surface on the first surface 211 side. As illustrated in FIG. 2, the first mounting region 31 has a quadrilateral shape in a plan view. Examples of the electronic component 7 mounted in the first mounting region 31 include a semiconductor integrated circuit element and an optoelectronic element. A corner portion of the first mounting region 31 and a corner portion of the electronic component 7 are mounted to overlap each other in a plane perspective view.

As illustrated in FIGS. 1 and 2, in the wiring board 1, the second mounting region 32 is located on the outermost surface on the first surface 211 side so as to surround the first mounting region 31. FIG. 2 is an explanatory diagram for explaining a state of the wiring board 1 when viewed from a direction indicated by an arrow A in FIG. 1. The second mounting region 32 is, for example, a region in which the stiffener 8 is provided in order to improve the rigidity of the wiring board 1.

The second laminate portion 12 is located on the second surface 212 of the first insulation layer 21. As the same as or similar to the first laminate portion 11, the second laminate portion 12 has a structure in which the electrical conductor layer 4 and the insulation layer are alternately laminated. At least two of the electrical conductor layers 4 and one of the insulation layers are laminated in the second laminate portion 12. The electrical conductor layer 4 and the insulation layer are as described above, and detailed description thereof will be omitted.

Of the insulation layers in the second laminate portion 12, the insulation layer located as the outermost layer is defined as a third insulation layer 23. That is, the insulation layer farthest from the second surface 212 is the third insulation layer 23. In the wiring board 1 illustrated in FIG. 1, since the second laminate portion 12 includes two of the insulation layers, the lower insulation layer is the third insulation layer 23.

Of the electrical conductor layers 4 in the second laminate portion 12, the electrical conductor layer 4 located as the outermost layer is defined as a first electrical conductor layer 41. That is, in the third insulation layer 23, the electrical conductor layer located on a second outer surface on the opposite side to the second surface 212 is the first electrical conductor layer 41. The first electrical conductor layer 41 is a planar electrical conductor layer having a planar shape. On the other hand, in the third insulation layer 23, the electrical conductor layer 4 located on a second inner surface on the second surface 212 side is defined as a second electrical conductor layer 42.

As illustrated in FIG. 1, the solder resist 5 is located on the surface (second outer surface) of the second laminate portion 12. Specifically, the solder resist 5 covers the second outer surface of the third insulation layer 23 and the first electrical conductor layer 41. The solder resist 5 is as described above, and detailed description thereof will be omitted.

In FIG. 1, the solder resist 5 provided on the surface (second outer surface) of the second laminate portion 12 is located on the surface of the first electrical conductor layer 41 and the second outer surface of the third insulation layer 23. The solder resist 5 located on the second outer surface of the third insulation layer 23 and the surface of the first electrical conductor layer 41 is formed with an opening 51b in order to electrically connect the first electrical conductor layer 41 and an electrode 61 of an external substrate 60 (for example, a motherboard or the like) via the solder 6.

When the wiring board 1 is viewed in a plane perspective view, in the first electrical conductor layer 41, a frame-shaped region 33 is located between the outer peripheral edge of the first mounting region 31 and the outer peripheral edge of the second mounting region 32. Specifically, the frame-shaped region 33 is a hatched portion illustrated in FIG. 3. FIG. 3 is an explanatory diagram for explaining a state when viewed from the direction indicated by the arrow B in FIG. 1.

In a plane perspective view, in the frame-shaped region 33, a through-hole conductor 43 that connects the first electrical conductor layer 41 and the second electrical conductor layer 42 is located across the edge of the opening 51b of the solder resist 5. The through-hole conductor 43 is not limited as long as it is a conductor, and is formed of, for example, metal plating such as copper plating. Since the through-hole conductor 43 having a rigidity higher than that of a resin is located at such a position, a binding force with respect to the first electrical conductor layer 41 is gradually alleviated. Thus, even if the wiring board 1 warps due to a difference in the coefficient of thermal expansion between the wiring board 1, the electronic component 7, and the stiffener 8, stress concentration at the periphery of the solder 6 connected to the first electrical conductor layer 41 is alleviated. As a result, even when the wiring board 1 is used in the environment in which the temperature repeatedly becomes high and low, cracks are less likely to occur.

The through-hole conductor 43 is not limited as long as it is located across the edge of the opening 51b in a plane perspective view. The edge of the opening 51b may be located substantially at the center of the through-hole conductor 43 in a plane perspective view, or the through-hole conductor 43 may be located closer to the outer side or the inner side of the opening 51b. Since stress tends to become larger from the edge of the opening 51b toward the outer side of the opening 51b than on the inner side of the opening 51b, when the edge of the opening 51b is located substantially at the center of the through-hole conductor 43, and also when the through-hole conductor 43 is located closer to the outer side of the opening 51b, the stress alleviating effect is further improved.

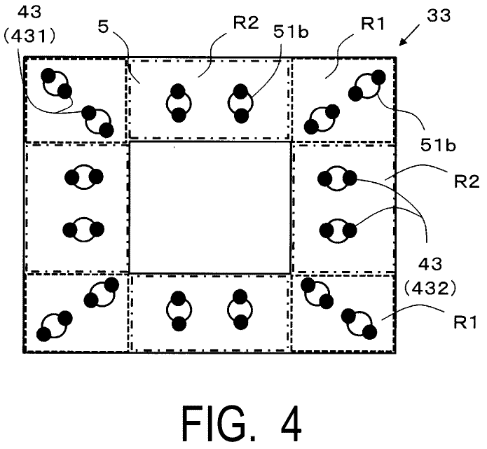

At least one of the through-hole conductors 43 may be located with respect to one of the openings 51b. For example, as illustrated in FIG. 4, the through-hole conductors 43 may be present at point-symmetrical positions with respect to the center of the opening 51b of the solder resist with the center acting as the point of symmetry. FIG. 4 is an explanatory diagram for explaining an example of the through-hole conductor 43.

Since the through-hole conductor 43 is disposed in such a manner, even if the warping occurs due to the difference in the coefficient of thermal expansion between the wiring board 1, the electronic component 7, and the stiffener 8, the stress concentration at the periphery of the solder 6 connected to the first electrical conductor layer 41 is further alleviated. As a result, even when the wiring board 1 is used in the environment in which the temperature repeatedly becomes high and low, cracks are less likely to occur. The “point-symmetrical position with respect to the center of the opening 51b of the solder resist with the center acting as the point of symmetry” can be defined as, for example, a midpoint of a line segment bisecting a length L described later, an intersection point of diagonal lines, or the center of gravity in each of the through-hole conductors 43.

The shape of the frame-shaped region 33 is determined in accordance with the shapes of the first mounting region 31 and the second mounting region 32. In the wiring board 1, as illustrated in FIG. 2, each of the first mounting region 31 and the second mounting region 32 has a quadrilateral shape in a plan view. Thus, as illustrated in FIG. 4, the frame-shaped region 33 has a quadrilateral frame shape having four corner portions R1 and four side portions R2.

The through-hole conductors 43 include first through-hole conductors 431 located in the corner portions R1 of the frame-shaped region 33 having the quadrilateral frame shape, and second through-hole conductors 432 located in the side portions R2 of the frame-shaped region 33. As illustrated in FIG. 4, the first through-hole conductors 431 are arranged in a first direction along a diagonal line connecting the corner portions R1 of the frame-shaped region 33. As illustrated in FIG. 4, the second through-hole conductors 432 are arranged in a second direction perpendicular to the side portion of the frame-shaped region 33 that is in close proximity to the second through-hole conductors 432.

When the frame-shaped region 33 has the quadrilateral frame shape, in the corner portions R1, stress is likely to occur in the first direction along the diagonal line connecting the corner portions R1, and in the side portions R2, stress is likely to occur in the second direction perpendicular to the side portion of the frame-shaped region 33. Therefore, as a result of the first through-hole conductors 431 and the second through-hole conductors 432s being located in the above-described manner, cracks are less likely to occur even when the wiring board 1 is used in the environment in which the temperature repeatedly becomes high and low.

As illustrated in FIG. 4, the solder resist 5 has a plurality of the openings 51b. As illustrated in FIG. 4, in a plane perspective view, the shape of the opening 51b may be, for example, a circular shape, or may be a shape other than the circular shape (for example, a polygonal shape such as a quadrilateral shape and a triangular shape, or an elliptical shape).

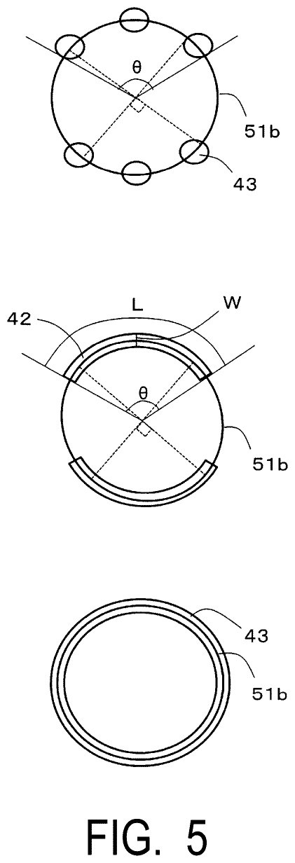

When the opening 51b has a circular shape, the through-hole conductor 43 may have a circular shape in a plan view, as illustrated in FIG. 4. In such a case, as illustrated in FIG. 5, a plurality of the through-hole conductors 43 each having the circular shape in a plane perspective view may be formed in an arc shape at the point-symmetrical positions with respect to the center of the opening 51b with the center acting as the point of symmetry. In this case, the length of the arc may be set such that an angle θ formed by virtual lines connecting the center of the opening 51b and the through-hole conductors 43 located at both end portions of the opening 51b, respectively, becomes 90° or greater. When the plurality of through-hole conductors 43 each having the circular shape are formed in the arc shape, the balance between the stress alleviating effect and the electrical characteristics becomes more favorable. FIG. 5 is an explanatory diagram for explaining variations of the through-hole conductor 43.

When the plurality of through-hole conductors 43 are provided at the point-symmetrical positions with respect to the center of the opening 51b with the center acting as the point of symmetry, the upper limit of the angle θ is preferably approximately 135°. This is advantageous in terms of improving dispersion of stress. The plurality of through-hole conductors 43 may be provided without considering the point-symmetrical positions with respect to the center of the opening 51 with the center acting as the point of symmetry and the angle θ.

When the opening 51b has a circular shape, the through-hole conductor 43 may have an arc shape in a plane perspective view, as illustrated in FIG. 5. When the through-hole conductor 43 has the arc shape, the through-hole conductor 43 may have a width W (a length in a direction orthogonal to the edge of the opening 51b) of at least 50 μm. The upper limit of the width W of the through-hole conductor 43 may be, for example, 80 μm. When the width W is set in such a range, the balance between the stress alleviating effect and the productivity of the through-hole conductor 43 becomes more favorable.

The length of the through-hole conductor 43 (the length L illustrated in FIG. 5) may be set, for example, such that the angle θ formed by the virtual lines connecting the center of the opening 51b and the two end portions of the through-hole conductor 43, respectively, is at least 90°. The upper limit of the angle θ is not limited, but the upper limit of the angle θ is preferably approximately 135° in order to provide the through-hole conductors 43 each having the arc shape at the point-symmetrical positions with respect to the center of the opening 51b with the center acting as the point of symmetry. When the through-hole conductors 43 each having the arc shape are provided, the balance between the stress alleviating effect and the electrical characteristics becomes more favorable. As illustrated in FIG. 5, the through-hole conductor 43 having an annular shape may be provided without considering the angle θ. When the through-hole conductor 43 has the annular shape, the stress alleviating effect is exhibited regardless of the direction of the stress.

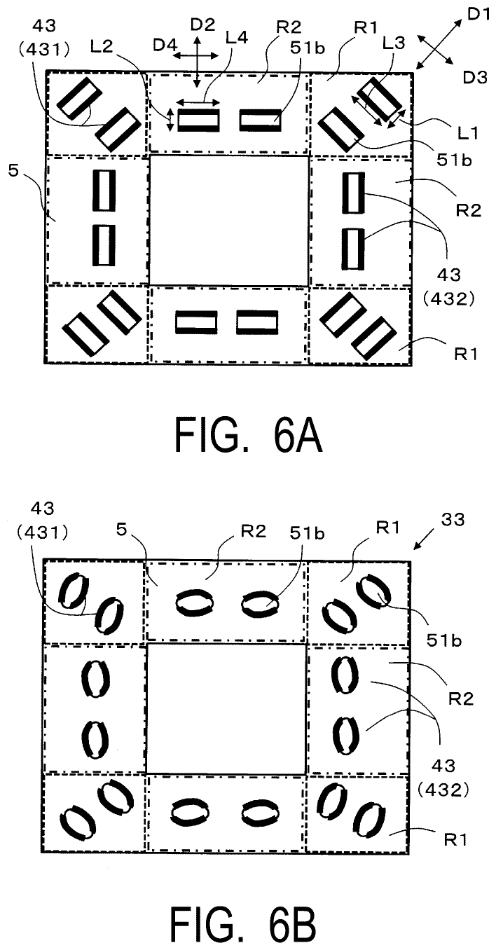

Between the outer periphery of the first mounting region 31 and the inner periphery of the second mounting region 32, as illustrated in FIG. 6, the opening 51b located in the corner portion R1 may have a third opening length L3 in a third direction D3 orthogonal to a first direction D1 that is greater than a first opening length L1 in the first direction, and the opening 51b located in the side portion R2 may have a fourth opening length L4 in a fourth direction D4 orthogonal to a second direction D2 that is greater than a second opening length L2 in the second direction D2. FIG. 6 is an explanatory diagram for explaining variations of the shape of the opening 51b formed in the solder resist 5 when the wiring board 1 according to the one embodiment of the present disclosure is viewed from the direction indicated by the arrow B in FIG. 1.

When the opening 51b has one of the shapes illustrated in FIG. 6, the tensile stress can be further alleviated compared with when the opening 51b has the circular shape as illustrated in FIG. 4. The tensile stress generated in the wiring board is likely to be generated in the first direction D1 and the second direction D2 between the outer periphery of the first mounting region 31 and the inner periphery of the second mounting region 32. Thus, by causing the length (the third length L3, the fourth length L4) of the opening edge in a direction (the third direction D3, the fourth direction D4) orthogonal to a generation direction (the first direction D1, the second direction D2) of the tensile stress to be greater than the length (the first length L1, the second length L2) of the opening edge in the generation direction of the tensile stress, the first electrical conductor layer 41 under the opening edge can receive the tensile stress in a wider range, and thus stress per unit length applied to the first electrical conductor layer 41 under the opening edge can be dispersed. Specifically, in a plane perspective view, the opening 51b located between the outer periphery of the first mounting region 31 and the inner periphery of the second mounting region 32 may have a rectangular shape as illustrated in FIG. 6A, or may have an elliptical shape as illustrated in FIG. 6B. The opening 51b having the rectangular shape and the opening 51b having the elliptical shape are formed, for example, in a portion in which the first electrical conductor layer 41 having a planar shape is located, between the outer periphery of the first mounting region 31 and the inner periphery of the second mounting region 32.

As illustrated in FIG. 6A, when the opening 51b has the rectangular shape, the aspect ratio of the opening 51b (the first length L1: the third length L3, the second length L2: the fourth length L4) is not limited, and may be, for example, in a range from 1:3.15 to 1:5. When the aspect ratio is set in such a range, the tensile stress can be further alleviated. As illustrated in FIG. 6B, when the opening 51b has the elliptical shape, the flat ratio is not limited, and may be, for example, in a range from 0.1 to 0.5. When the flat ratio is set in such a range, the tensile stress can be further alleviated.

All of the openings 51b formed in the solder resist 5 may have substantially the same opening area. When the opening 51b has substantially the same opening area, an amount of the solder 6 can be made substantially constant when the electronic component 7 is mounted, and the mounting reliability can be improved. In the present specification, “substantially the same opening area” means an area within a range of +10% of a reference opening area.

The wiring board 1 as described above is formed, for example, as follows. First, the first insulation layer 21 is prepared. Through holes are formed in the first insulation layer 21 by drilling, blasting, or laser machining. Subsequently, the electrical conductor layer 4 and the insulation layer are alternately laminated on the first surface 211 side and the second surface 212 side of the first insulation layer 21. When the electrical conductor layer 4 is formed on the surface of the first insulation layer 21 by, for example, copper plating using a semi-additive method, the through-hole metal 2a may be formed in the through-hole, or the through-hole metal 2a may be formed in the through hole in advance. A method for forming the electrical conductor layer 4 and the through-hole metal 2a is as described above, and detailed description thereof will be omitted.

The insulation layer is formed by applying a film made of a resin such as an epoxy resin, a bismaleimide-triazine resin, a polyimide resin, and a polyphenylene ether resin under vacuum and thermally curing the film. By performing laser machining on the insulation layer, a via hole having the electrical conductor layer 4 as a bottom portion is formed. After the laser machining, desmear treatment for removing resin smear, carbide or the like is performed to improve the adhesion strength between the via hole and the via-hole metal 2b. When the electrical conductor layer 4 is formed on the surface of the insulation layer, for example, using the semi-additive method, the via-hole metal 2b is formed of plating metal in the via hole.

By repeating the step of forming the electrical conductor layer 4 and the step of forming the insulation layer, a desired number of the electrical conductor layers 4 and the insulation layers are formed, and the first laminate portion 11 and the second laminate portion 12 are formed. Of the insulation layers of the first laminate portion 11, the insulation layer located as the outermost layer is referred to as the second insulation layer 22, and of the insulation layers of the second laminate portion 12, the insulation layer located as the outermost layer is referred to as the third insulation layer 23.

As described above, in the third insulation layer 23, the electrical conductor layer 4 located on the second outer surface on the opposite side to the second surface 212 is the first electrical conductor layer 41 having the planar shape. On the other hand, in the third insulation layer 23, the electrical conductor layer 4 located on the second inner surface on the second surface 212 side is the second electrical conductor layer 42.

When the above-described via hole is formed, the through hole for forming the through-hole conductor 43 that connects the first electrical conductor layer 41 and the second electrical conductor layer 42 is also formed in the third insulation layer 23. The through hole is formed extending across the edge of the opening 51b of the solder resist 5 described later. When forming the via-hole metal 2b, the through-hole conductor 43 is formed of, for example, the same conductor as the via-hole metal 2b.

Subsequently, the surface (first outer surface) of the first laminate portion 11 and the surface (second outer surface) of the second laminate portion 12 are covered with the solder resist 5. In the solder resist 5 covering the surface (first outer surface) of the first laminate portion 11, the opening 51a is formed in a region that forms the first mounting region 31. In the solder resist 5 covering the surface (second outer surface) of the second laminate portion 12, the opening 51b for electrically connecting the first electrical conductor layer 41 and the electrode 61 of the external substrate 60 (for example, the motherboard or the like) via the solder 6 is formed.

In the above-described manner, the wiring board 1 according to the one embodiment is obtained. Since the through-hole conductors 43 are disposed in the wiring board 1, even if the warping occurs due to the difference in the coefficient of thermal expansion between the wiring board 1, the electronic component 7, and the stiffener 8, the stress concentration at the periphery of the solder 6 connected to the first electrical conductor layer 41 is alleviated. As a result, cracks are less likely to occur even when the wiring board 1 is used in the environment in which the temperature repeatedly becomes high and low.

The mounting structure according to the present disclosure includes the wiring board 1 according to the one embodiment, the electronic components 7 located in the first mounting region 31 of the wiring board 1, the stiffener 8 located in the second mounting region 32, and the external substrate including the electrode 61. The first electrical conductor layer 41 inside the opening 51b of the solder resist 5 and the electrode 61 are connected via the solder 6. As described above, examples of the electronic component 7 include a semiconductor integrated circuit element and an optoelectronic element.

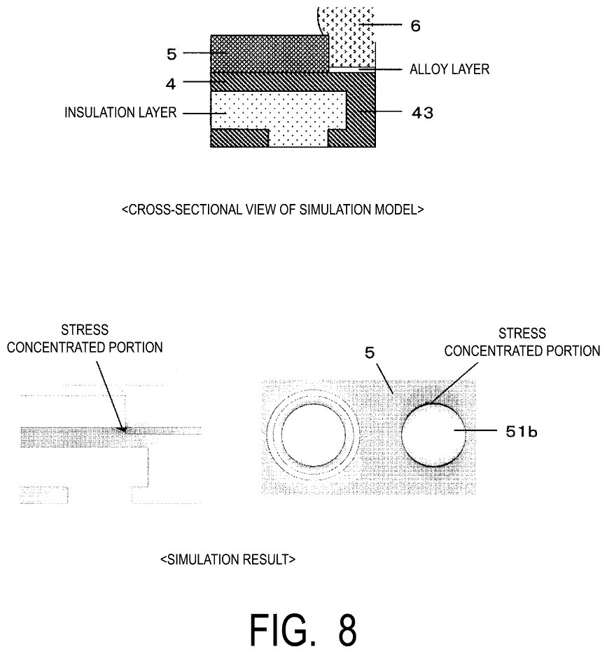

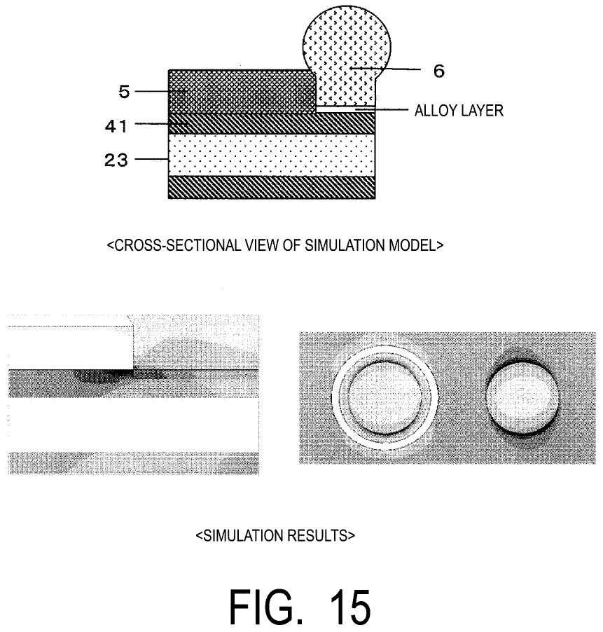

With respect to the known mounting structure and the mounting structure according to the present disclosure, cross-sectional views of simulation models and simulation results (stress distribution diagrams) in which different shapes and positions of the through-hole conductors 43 are provided in the wiring board are illustrated in FIGS. 8 to 18. These results were obtained under the conditions shown in Table 1 below. In the stress distribution diagram, a darker color indicates a higher stress value. ABF GL102F shown in Table 1 is a heat-curable build-up film manufactured by Ajinomoto Fine-Techno Co., Inc. “SR” shown in Table 1 is a solder resist, and “SR7300G” is a photosensitive solder resist manufactured by Resonac Corporation.

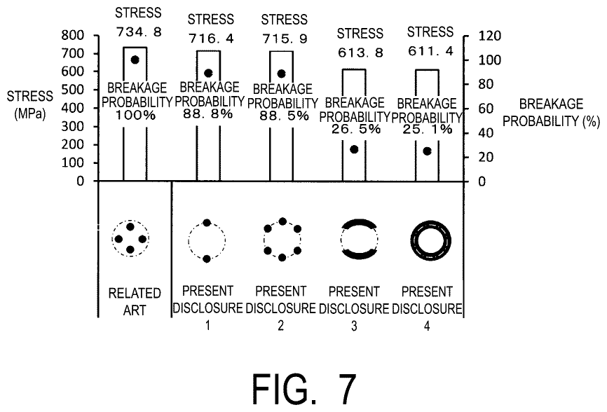

With respect to the known mounting structure, as illustrated in FIG. 7, a wiring board was used in which the through-hole conductors 43 each having a circular shape are located inside the opening 51b of the solder resist 5 in a plane perspective view. On the other hand, with respect to mounting structures according to first to fourth embodiments of the present disclosure, as illustrated in FIG. 7, four types of wiring boards were used in which the through-hole conductors 43 each having a circular shape, the through-hole conductors 43 each having an arc shape, or the through-hole conductor having an annular shape are located across the opening 51b of the solder resist 5 in a plane perspective view. In the known mounting structure, as illustrated in FIG. 8, it can be confirmed that a large stress is applied to the conductor layer 4 under the opening edge of the solder resist 5.

TABLE 1

| | ELASTIC MODULUS | | | | | | | | | |
|---|---|---|---|---|---|---|---|---|---|---|
| | (GPa) | | | | CTE (ppm/° C.) | | | | | |
| | T < Tg | | Tg < T | | α1 (T < Tg) | | α2 (Tg < T) | | | POISSON |
| MATERIAL | XY | Z | XY | Z | XY | Z | XY | Z | Tg | RATIO |
| CONDUCTOR | 70 | 70 | — | — | 17 | 17 | — | — | — | 0.3 |
| SECOND AND THIRD | 13 | 13 | 0.4 | 0.4 | 20 | 20 | 49 | 49 | 153 | 0.3 |
| INSULATION LAYERS | | | | | | | | | | |
| (ABF GL102F) | | | | | | | | | | |
| SR (SR7300G) | 2.6 | 2.6 | 0.3 | 0.3 | 38 | 39 | 115 | 115 | 130 | 0.3 |
| FIRST INSULATION | 25 | 17 | — | — | 4.6 | 2 | — | — | 260 | 0.3 |
| LAYER (CORE) | | | | | | | | | | |
| CHIP | 131 | 131 | — | — | 2.6 | 2.6 | — | — | — | 0.3 |
| STIFFENER | 118 | 118 | — | — | 17.6 | 17.6 | — | — | — | 0.33 |
| UNDERFILL | 6.5 | 6.5 | 0.35 | 0.35 | 33 | 33 | 115 | 115 | 115 | 0.3 |
| SOLDER | 34 | 34 | — | — | 22.6 | 22.6 | — | — | — | 0.3 |
| SOLDER ALLOY | 110 | 110 | — | — | 16 | 16 | — | — | — | 0.35 |
| LAYER | | | | | | | | | | |
| STIFFENER | 7.2 | 7.2 | — | — | 200 | 200 | — | — | — | 0.45 |
| ADHESIVE | | | | | | | | | | |
| SEALING RESIN | 18.5 | 18.5 | — | — | 9.8 | 9.8 | 42 | 42 | 151 | 0.3 |

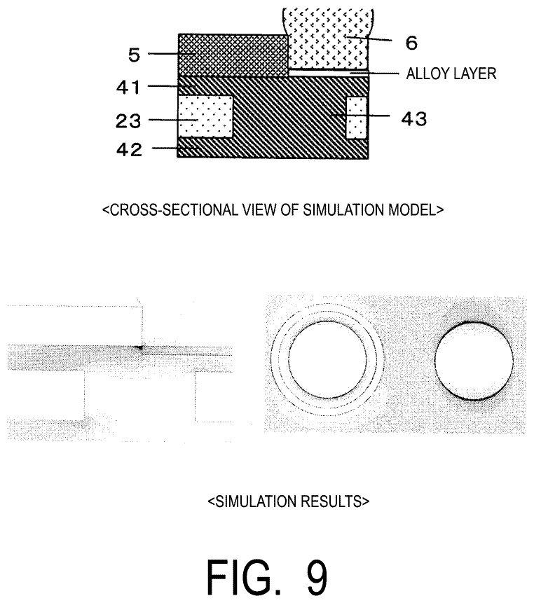

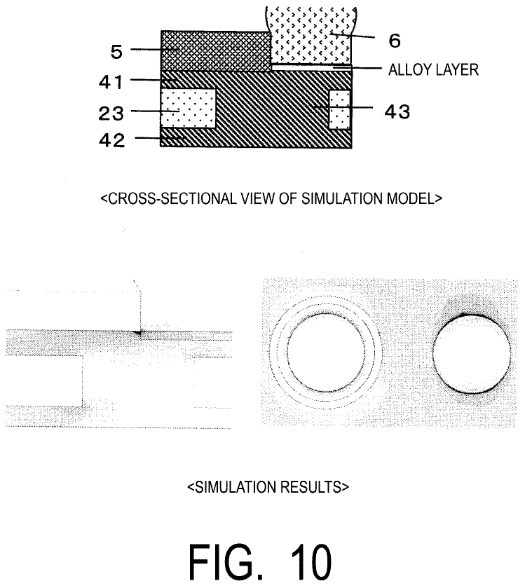

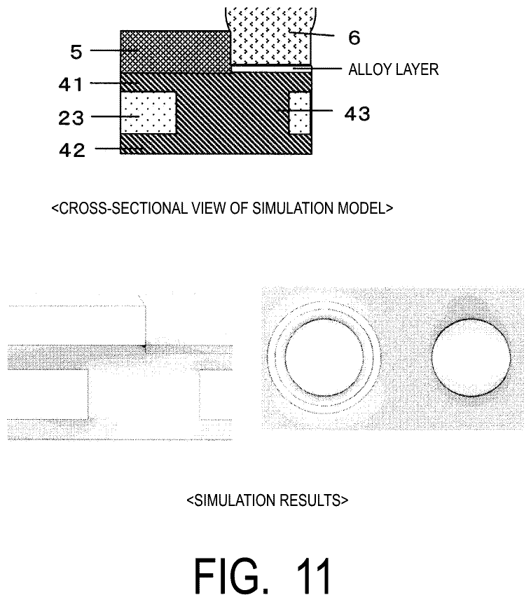

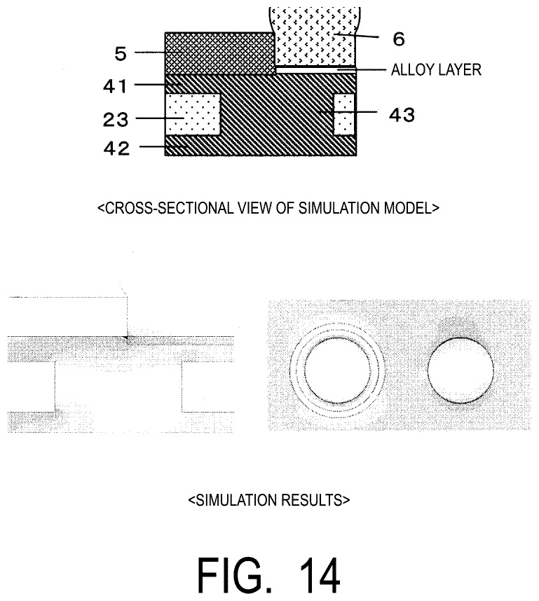

As illustrated in FIGS. 7 and 9, in the mounting structure according to the first embodiment of the present disclosure, the stress is reduced by approximately 18.4 MPa as compared with the known mounting structure, and it can be understood from the stress distribution diagram that the stress applied to the first electrical conductor layer 41 under the opening edge of the solder resist 5 is reduced. As illustrated in FIGS. 7 and 10, in the mounting structure according to the second embodiment of the present disclosure, the stress is reduced by approximately 18.9 MPa as compared with the known mounting structure, and it can be understood from the stress distribution diagram that the stress applied to the first electrical conductor layer 41 under the opening edge of the solder resist 5 is further reduced. As illustrated in FIGS. 7 and 11, in the mounting structure according to the third embodiment of the present disclosure, the stress is reduced by approximately 121 MPa as compared with the known mounting structure, and it can be understood from the stress distribution diagram that the stress applied to the first electrical conductor layer 41 under the opening edge of the solder resist 5 is further reduced as compared with the first and second embodiments of the present disclosure. As illustrated in FIGS. 7 and 14, in the mounting structure according to the fourth embodiment of the present disclosure, the stress is reduced by approximately 123.4 MPa as compared with the known mounting structure, and it can be understood from the stress distribution diagram that the stress applied to the first electrical conductor layer 41 under the opening edge of the solder resist 5 is further reduced as compared with the first, second, and third embodiments of the present disclosure.

With respect to the mounting structures according to the first to fourth embodiments of the present disclosure, when the breakage probability is measured (calculated) if the breakage probability of the known mounting structure is set to 100%, it can be understood that the breakage probability is reduced by 10% or more, and in the examples in which the wiring board including the through-hole conductor 43 having the arc shape or the annular shape was used, the breakage probability is reduced by 70% or more. From the description above, it can be understood that a slight reduction in the stress, that is, a reduction in the stress by a small percentage, significantly contributes to a reduction in the breakage probability. The breakage probability in the present disclosure is calculated by dividing ((the stress value generated in the electrical conductor layer under the opening edge)−(the stress value generated in the island-shaped electrical conductor layer under the opening edge in the structure of the present disclosure)) by ((the stress value generated in the electrical conductor layer under the opening edge)−(the stress value generated in the island-shaped electrical conductor layer under the opening edge in the known structure)). That is, when the stress value generated in the island-shaped electrical conductor layer, which is located under the opening edge of the solder resist 5 so as to be separated from the surrounding electrical conductor layer and in which no cracks are observed, is used as a reference, the breakage probability is a percentage of the stress value excessively applied to the electrical conductor layer of the structure of the present disclosure with respect to the stress value excessively applied to the electrical conductor layer having the known structure, and is an index that is used to estimate the occurrence probability of the cracks.

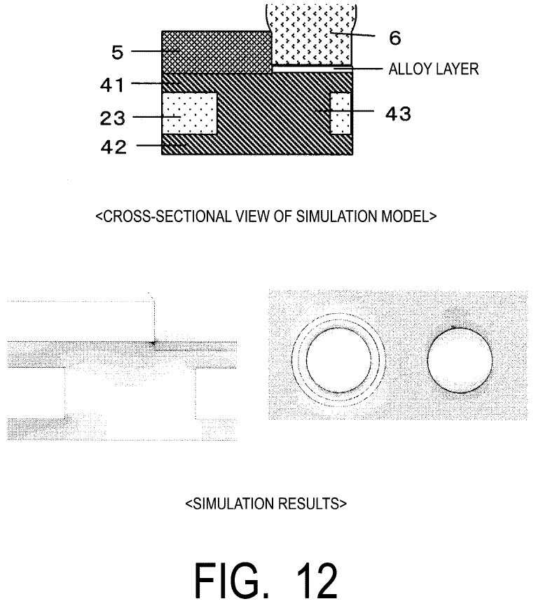

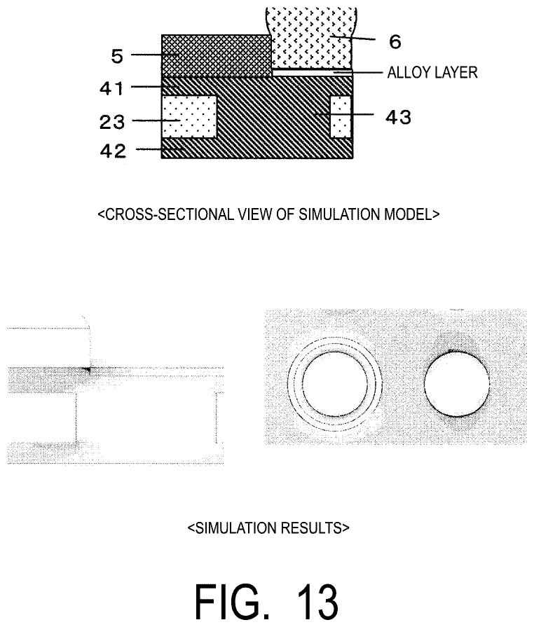

With respect to the example in which the wiring board including the through-hole conductors 43 each having the arc shape was used, a difference in the stress alleviating effect due to the position of the through-hole conductor 43 was examined. First, as illustrated in the third embodiment of the present disclosure in FIG. 7 and the cross-sectional view of the simulation model in FIG. 11, when the edge of the opening 51b is located substantially at the center of the through-hole conductor 43 in a plane perspective view, the stress was 613.8 MPa. On the other hand, as illustrated in the cross-sectional view of the simulation model in FIG. 12, when the through-hole conductor 43 was located closer to the outer side of the opening 51b in a plane perspective view, the stress was 617.3 MPa. Further, as illustrated in the cross-sectional view of the simulation model in FIG. 13, when the through-hole conductor 43 was located closer to the inner side of the opening 51b in a plane perspective view, the stress was 685.4 MPa. From these results, it can be understood that the stress alleviating effect is higher when the edge of the opening 51b is located substantially at the center of the through-hole conductor 43 and when the through-hole conductor 43 is located closer to the outer side of the opening 51b than when the through-hole conductor 43 is located closer to the inner side of the opening 51b.

The wiring board of the present disclosure is not limited to the above-described embodiments. In the wiring board 1 according to the one embodiment, the first mounting region 31 has the quadrilateral shape in a plan view. However, in the wiring board according to the present disclosure, the shape of the first mounting region is appropriately set according to the shape of the electronic component, and may be a polygonal shape such as a triangular shape, a pentagonal shape, or a hexagonal shape, or may be a circular shape or an elliptical shape in a plan view.

In the wiring board 1 according to the one embodiment, the second mounting region 32 has the quadrilateral frame shape in a plan view. However, in the wiring board according to the present disclosure, the shape of the second mounting region is not limited, and may be a polygonal frame shape such as a triangular frame shape, a pentagonal frame shape, or a hexagonal frame shape, or may be a circular ring shape or an elliptical ring shape in a plan view.

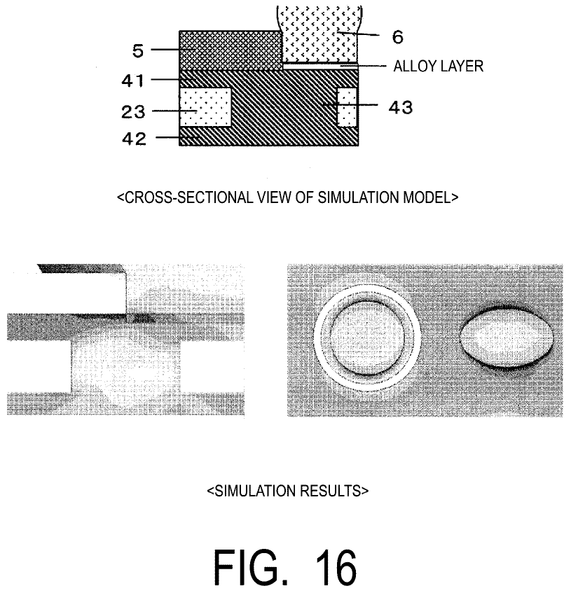

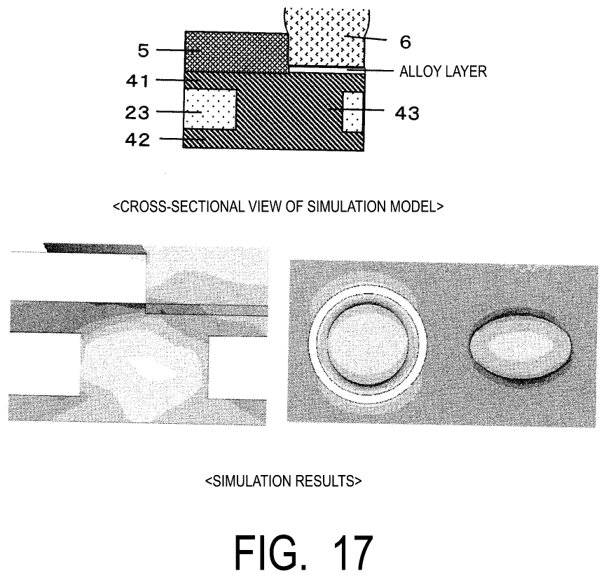

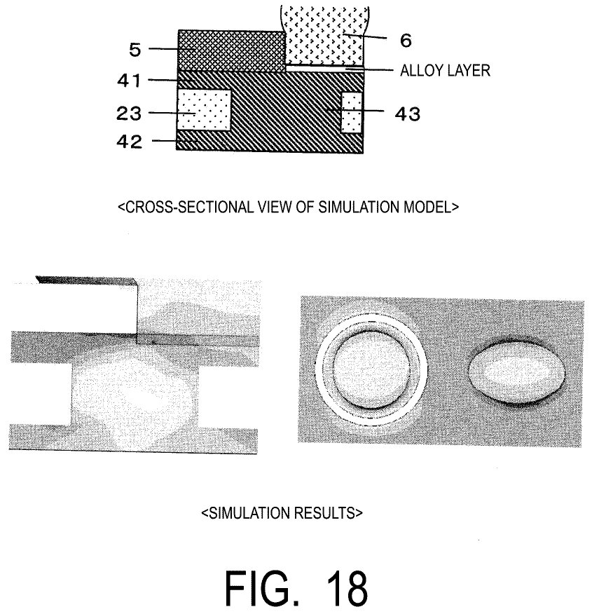

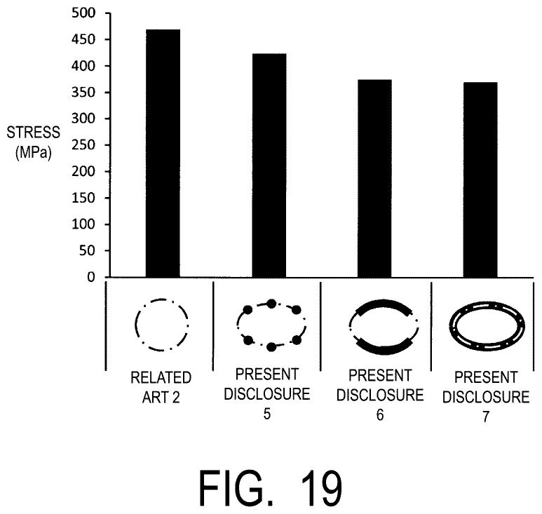

As illustrated in FIGS. 16 and 19, in the mounting structure according to a fifth embodiment of the present disclosure, the stress is reduced by approximately 45 MPa as compared with a mounting structure according to a second example of related art, and it can be understood from the stress distribution diagram that the stress applied to the first electrical conductor layer 41 under the opening edge of the solder resist 5 is reduced. As illustrated in FIGS. 17 and 19, in the mounting structure according to a sixth embodiment of the present disclosure, the stress is reduced by approximately 93.9 MPa as compared with the mounting structure according to the second known example, and it can be understood from the stress distribution diagram that the stress applied to the first electrical conductor layer 41 under the opening edge of the solder resist 5 is further reduced. As illustrated in FIGS. 18 and 19, in the mounting structure according to a seventh embodiment of the present disclosure, the stress is reduced by approximately 98.5 MPa as compared with the mounting structure according to the second known example, and it can be understood from the stress distribution diagram that the stress applied to the first electrical conductor layer 41 under the opening edge of the solder resist 5 is further reduced as compared with the fifth and sixth embodiments of the present disclosure.

In the wiring board 1 according to the one embodiment, a pair of the through-hole conductors 43 located at the point-symmetrical positions with respect to the center of the opening 51b of the solder resist 5 with the center acting as the point of symmetry have the same shape and the same size. However, the shape and the size may be different from each other depending on the magnitude of stress generated around the opening 51b. This makes it easier to keep the balance between the dispersion of stress and the electrical characteristics.

### REFERENCE SIGNS

1 Wiring board
11 First laminate portion
12 Second laminate portion
21 First insulation layer
22 Second insulation layer
23 Third insulation layer
211 First surface
212 Second surface
2a Through-hole conductor
2b Via-hole conductor
31 First mounting region
32 Second mounting region
33 Frame-shaped region
4 Electrical conductor layer
41 First electrical conductor layer
42 Second electrical conductor layer
43 Through-hole conductor
431 First through-hole conductor
432 Second through-hole conductor
5 Solder resist
51b Opening (of a solder resist on a third insulation layer side)
60 External substrate
61 Electrode
6 Solder
7 Electronic component
8 Stiffener

1. A wiring board comprising:
a first insulation layer having a first surface and a second surface located on an opposite side to the first surface;
a first laminate portion located on the first surface and comprising insulation layers;
a second laminate portion located on the second surface and comprising insulation layers;
a second insulation layer located as an outermost layer of the insulation layers in the first laminate portion;
a third insulation layer located as an outermost layer of the insulation layers in the second laminate portion;
a first mounting region located on a first outer surface on an opposite side to the first surface in the second insulation layer;
a second mounting region located on the first outer surface to surround the first mounting region in the second insulation layer;
a first electrical conductor layer having a planar shape and located on a second outer surface on an opposite side to the second surface in the third insulation layer;
a second electrical conductor layer located on a second inner surface on the second surface side in the third insulation layer; and
a solder resist covering the second outer surface of the third insulation layer and the first electrical conductor layer, and having an opening from which a part of the first electrical conductor layer is exposed, wherein
in a plane perspective view, in a frame-shaped region between an outer peripheral edge of the first mounting region and an outer peripheral edge of the second mounting region, a through-hole conductor configured to connect the first electrical conductor layer and the second electrical conductor layer is located across an edge of the opening.

2. The wiring board according to claim 1, wherein
the through-hole conductors are located at point-symmetrical positions with respect to a center of the opening, the center acting as a point of symmetry.

3. The wiring board according to claim 1, wherein
the frame-shaped region has a quadrilateral frame shape comprising four corner portions and four side portions in a plan view,
the solder resist has a plurality of the openings,
the through-hole conductors are located corresponding to the plurality of openings, respectively,
the through-hole conductors comprise first through-hole conductors located in the corner portions of the quadrilateral frame-shape, and second through-hole conductors located in the side portions of the quadrilateral frame-shape,
the first through-hole conductors are located along a first direction extending along a diagonal line connecting the corner portions, and
the second through-hole conductors are located along a second direction perpendicular to the side portion that is in close proximity to the second through-hole conductors.

4. The wiring board according to claim 1, wherein
in a plane perspective view, the opening has a circular shape and the through-hole conductor has a circular shape.

5. The wiring board according to claim 1, wherein
in a plane perspective view, the opening has a circular shape and the through-hole conductor has an arc shape.

6. The wiring board according to claim 1, wherein
in a plane perspective view, the opening has a circular shape and the through-hole conductor has an annular shape.

7. The wiring board according to claim 6, wherein
the frame-shaped region has a quadrilateral frame-shape comprising four corner portions and four side portions in a plan view,
the solder resist has a plurality of the openings,
the through-hole conductors are located corresponding to the plurality of openings, respectively, and
the through-hole conductors comprise a first through-hole conductor located in the corner portions of the quadrilateral frame-shape, and a second through-hole conductor located in the side portions of the quadrilateral frame-shape.

8. The wiring board according to claim 3, wherein
in a plane perspective view, between an outer peripheral edge of the first mounting region and an inner peripheral edge of the second mounting region, when the opening located in the corner portion has a first length that is a length of the opening in the first direction, a second length that is a length of the opening in the second direction, a third length that is a length of the opening in a third direction orthogonal to the first direction, and a fourth length that is a length of the opening in a fourth direction orthogonal to the second direction, the third length is greater than the first length and the fourth length is greater than the second length.

9. The wiring board according to claim 8, wherein
each of a ratio between the first length and the third length, and a ratio between the second length and the fourth length is in a range from 1:3.15 to 1:5.

10. The wiring board according to claim 8, wherein
a flat ratio of the opening is in a range from 0.1 to 0.5.

11. The wiring board according to claim 1, wherein
each of the plurality of openings has the same area.

12. The wiring board according to claim 1, wherein
the through-hole conductor has a length of at least 50 μm in a direction orthogonal to the edge of the opening.

13. A mounting structure comprising:
the wiring board according to claim 1;
an electronic component located in the first mounting region;
a stiffener located in the second mounting region; and
an external substrate comprising an electrode, wherein
the first electrical conductor layer inside the opening and the electrode are connected to each other via a solder.
